(19) United States
(12) Patent Application Publication
(10) Pub. No.: US 2026/0096038 A1
(43) Pub. Date: Apr. 2, 2026

(54) WIND RESISTANT GENERATOR SET ENCLOSURE

(71) Applicant: Chongqing Hudson New Energy Co., Ltd., Chongqing (CN)

(72) Inventors: Sheng Li, Chongqing (CN); Hui Yang, Chongqing (CN)

(21) Appl. No.: 19/341,245

(22) Filed: Sep. 26, 2025

(30) Foreign Application Priority Data
Sep. 27, 2024 (CN) 202422375273.6

(51) Int. Cl. H05K 5/02; H02K 5/22; H05K 5/03

(52) U.S. Cl. CPC H05K 5/0226; H02K 5/22; H05K 5/03

(57) ABSTRACT

Systems of the present disclosure provide a chassis and a generator set, including a cabinet, a cover plate and hinge mechanisms. Each hinge mechanism includes a first connection seat, a second connection seat and a connection assembly. The first connection seat is arranged on the cover plate, and a slider is arranged on the first connection seat. The second connection seat is arranged in the cabinet, and the length of the second connection seat is less than the length of the first connection seat. When the cover plate is at the maximum opening and closing position, the center of mass of the cover plate is located above the top surface of the cabinet and close to the top surface of the cabinet.

### FIELD OF THE INVENTION

The present invention generally relates to the field of generator set cabinets, in particular to a cabinet and a generator set.

### BACKGROUND OF THE INVENTION

A mute box-type generator set has the sound insulation effect, and the generated noise can be effectively reduced by installing the generator and the engine in a case, so that the generator set can operate more quietly.

However, an existing case cover plate generally adopts a conventional hinge structure, where the opening angle of the cover plate is smaller, the barycenter of the cover plate is higher after the cover plate is opened, and correspondingly, the windward area of the inner side of the cover plate is larger. In windy weather, if the cover plate is in an open state, the cover plate can be blown into a closed position. In some scenarios, a strong wind can move the cover plate to flip the case over.

Moreover, the hinge structure of the existing case is usually exposed, and after time, the hinge structure can deteriorate, such that the connection between the cover plate and the case becomes unstable, and the cover plate is likely to be enforced to close or separated from the case by a strong wind. Thus, it is necessary to develop a generator enclosure with improved cover and hinge design to resist strong wind.

### BRIEF DESCRIPTION OF THE DRAWINGS

In order to more clearly illustrate the embodiments of the present application or the technical solutions in the prior art, the drawings used in the description of the embodiments or the prior art will be briefly described below. Like elements or portions are generally identified by like reference numerals throughout the several figures. In the drawings, elements or portions thereof are not necessarily drawn to scale. Embodiments of the invention are described with reference to the following figures. The same numbers are used throughout the figures to reference like features and components. The features depicted in the figures are not necessarily shown to scale. Certain features of the embodiments may be shown exaggerated in scale or in somewhat schematic form, and some details of elements may not be shown in the interest of clarity and conciseness.

FIG. 1 is a schematic structural diagram of a chassis according to an embodiment of the present application;

FIG. 2 is a schematic view of the cover plate in a maximum open and closed position;

FIG. 3 is a schematic view of the hinge mechanism when the cover is in the maximum open position;

FIG. 4 is a partial schematic view of FIG. 1 at A;

FIG. 5 is a schematic view of the structure of the first mounting member;

FIG. 6 is a schematic cross-sectional view of the first mounting member mated with the first connector base;

FIG. 7 is a schematic view of a hinge mechanism from another perspective;

FIG. 8 is a schematic view of a hinge structure with a cover plate in a closed state; and

FIG. 9 is a schematic view of the structure of the inside of the case.

### DETAILED DESCRIPTION

Embodiments of the technical scheme of the present application will be described in detail below with reference to the accompanying drawings. The following examples are only for more clearly illustrating the technical aspects of the present application, and thus are merely examples, and are not intended to limit the scope of the present application.

It is noted that unless otherwise indicated, technical or scientific terms used herein should be given the ordinary meaning as understood by one of ordinary skill in the art to which the present application belongs.

In the description of the present application, it should be understood that the terms “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, etc. indicate orientations or positional relationships based on the orientations or positional relationships shown in the drawings are merely for convenience in describing the present application and simplifying the description, and do not indicate or imply that the device or element being referred to must have a specific orientation, be configured and operated in a specific orientation, and therefore should not be construed as limiting the present application.

Furthermore, the terms “first,” “second,” and the like, are used for descriptive purposes only and are not to be construed as indicating or implying a relative importance or implicitly indicating the number of technical features indicated. In the description of the present application, the meaning of “plurality” is two or more unless specifically defined otherwise.

In the present application, unless explicitly specified and limited otherwise, the terms “mounted,” “connected,” “secured,” and the like are to be construed broadly, and may be, for example, fixedly connected, detachably connected, or integrally formed, mechanically connected, electrically connected, directly connected, indirectly connected via an intervening medium, or in communication between two elements or in an interaction relationship between two elements. The specific meaning of the above terms in the present application can be understood by those of ordinary skill in the art according to the specific circumstances.

In the present application, unless expressly stated or limited otherwise, a first feature “up” or “down” a second feature may be the first and second features in direct contact, or the first and second features in indirect contact via an intervening medium. Moreover, a first feature being “above,” “over” and “on” a second feature may be a first feature being directly above or obliquely above the second feature, or simply indicating that the first feature is level higher than the second feature. The first feature being “under”, “below” and “beneath” the second feature may be the first feature being directly under or obliquely below the second feature, or simply indicating that the first feature is less level than the second feature.

Aiming at the defects in the prior art, the present application aims to provide a case and a generator set so as to improve the windproof and wind-resistant effects of a cover plate and reduce potential safety hazards.

The present application provides a case which comprises a case body, a cover plate and two hinge mechanisms, wherein the top of the case body is provided with an opening, the cover plate is used for opening or covering the opening of the case body, the hinge mechanisms are arranged at intervals, each hinge mechanism is respectively connected with the cover plate and the case body, each hinge mechanism comprises a first connecting seat, a second connecting seat and a connecting component, the first connecting seat is arranged on the cover plate, the length direction of the first connecting seat is parallel to the width direction of the cover plate, a sliding block capable of sliding along the length direction of the first connecting seat is arranged on the first connecting seat, the second connecting seat is arranged in the case body, the length of the second connecting seat is smaller than the length of the first connecting seat, and the connecting component is respectively hinged with the first connecting seat, the sliding block and the second connecting seat;

When the cover plate is positioned at the maximum opening and closing position, part of the plate body of the cover plate moves to the rear side of the box body, and the mass center of the cover plate is positioned above the top surface of the box body and is close to the top surface of the box body.

Preferably, two reinforcing beams are arranged on the inner side of the cover plate, the reinforcing beams extend along the width direction of the cover plate, each reinforcing beam corresponds to one first connecting seat, and the first connecting seats are arranged on the reinforcing beams.

Preferably, the stiffening beam is provided with a first mounting part, the first mounting part comprises a first plate body and a second plate body which are connected, the first plate body is arranged on the stiffening beam, a yielding gap is formed between the second plate body and the stiffening beam, and the first connecting seat is arranged on one side, deviating from the stiffening beam, of the second plate body.

Preferably, the first connecting seat is provided with a plurality of first through holes, the second plate body is provided with a plurality of second through holes, each second through hole corresponds to one first through hole, the second plate body is fixedly provided with a plurality of nuts, the nuts are located in the yielding gaps, and each nut corresponds to one second through hole.

Preferably, the connecting assembly comprises a first connecting arm, a second connecting arm and a third connecting arm, two ends of the first connecting arm are hinged to the first connecting seat and the second connecting seat respectively, two ends of the second connecting arm are hinged to the sliding block and the second connecting seat respectively, and two ends of the third connecting arm are hinged to the first connecting arm and the sliding block respectively.

Preferably, the connecting assembly further comprises a fourth connecting arm, and two ends of the fourth connecting arm are respectively connected with the third connecting arm and the second connecting seat.

Preferably, a second mounting piece and a third mounting piece are arranged in the box body, the two second connecting seats are respectively arranged on the second mounting piece and the third mounting piece, a third through hole is formed in the third mounting piece, and a shutter is arranged on a side plate, close to the third mounting piece, of the box body.

Preferably, the third mounting member divides the inner cavity of the case into a first chamber and a second chamber, the first chamber is communicated with the second chamber through hole and the third through hole, and the second chamber is located between the third through hole and the louver.

The present application also provides a generator set, which comprises the case. The present application has the beneficial effects that: according to the case and the generator set disclosed by the present application, when the cover plate is positioned at the maximum opening and closing position, the center of mass of the cover plate is positioned above the top surface of the case body and is close to the top surface of the case body, and as part of the plate body of the cover plate moves to the rear side of the case body, the windward area of the inner side of the cover plate is reduced, and wind is not easy to blow the cover plate in an opening state, so that the cover plate can still be kept in the opening state, the problem that the opened cover plate is easily closed due to the blowing of wind is avoided, the wind prevention and wind resistance effects of the cover plate are improved, the potential safety hazard is reduced, and the normal use of the case is ensured. Meanwhile, the hinge mechanism is not exposed outside, so that the service life of the hinge mechanism is prolonged, and the firmness of connection of the cover plate and the box body is ensured.

And, the first connecting seat that length is long is installed on the apron, and the second connecting seat that length is short is installed in the box, therefore, the second connecting seat that length is short can not excessively encroach on the inner space of box to can not influence the installation of other spare part.

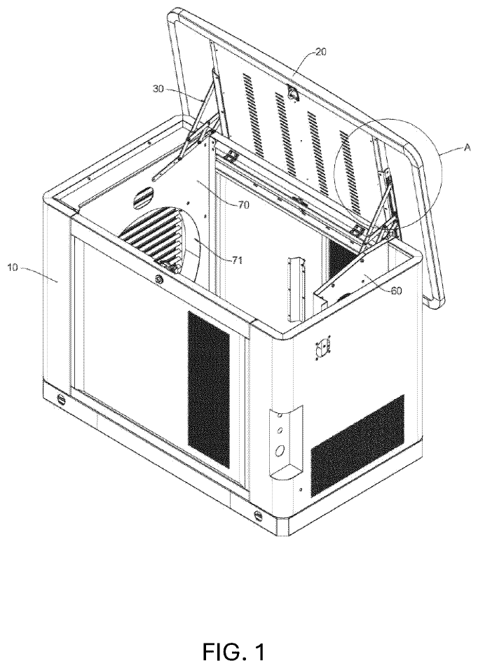

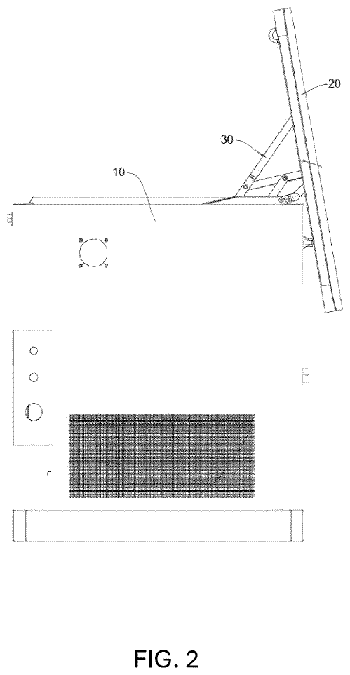

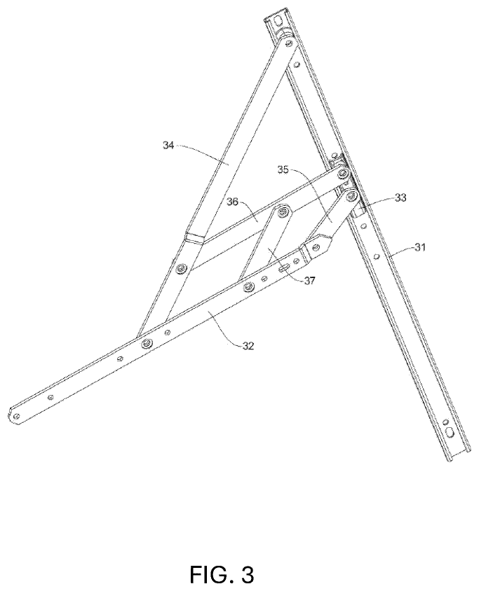

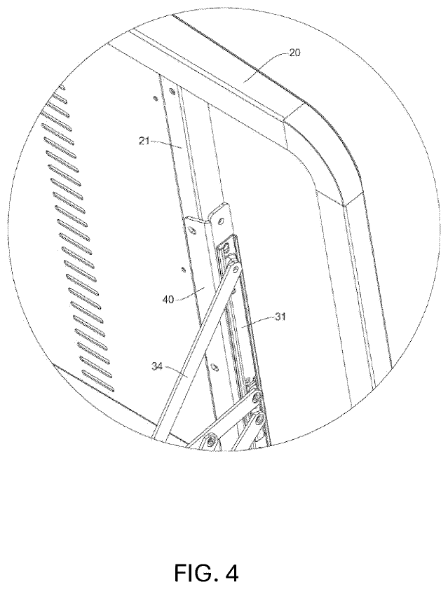

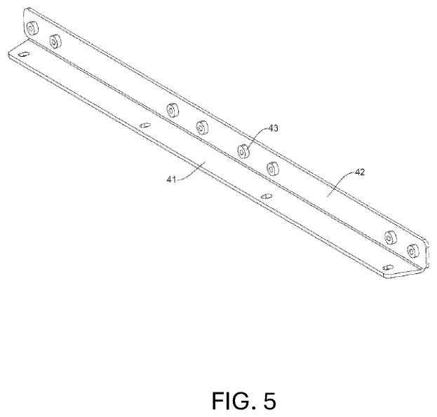

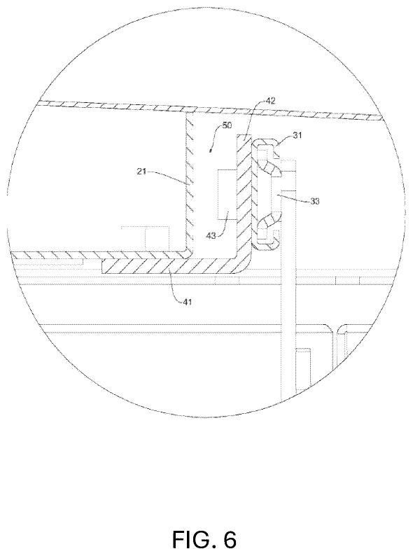

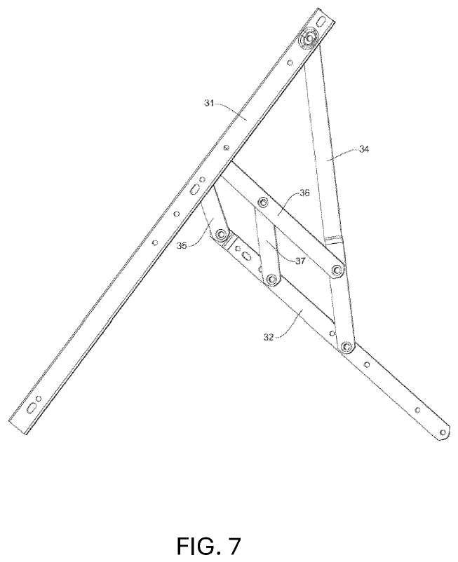

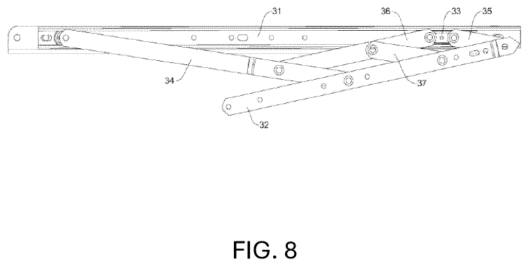

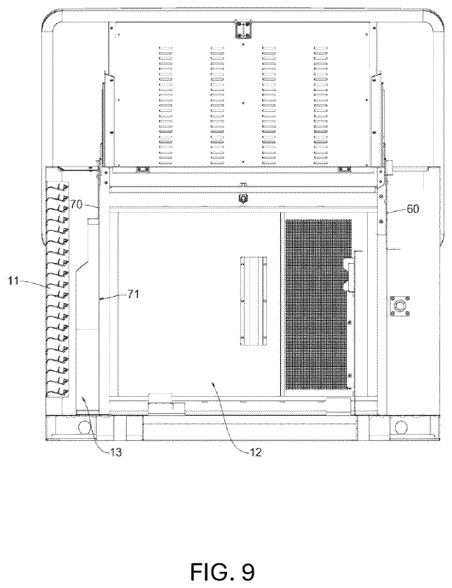

As shown in FIGS. 1 to 9, in an embodiment of the present application, there is provided a cabinet 10 (e.g., a case, a box body), a cover 20 and two hinge mechanisms 30. The top of the cabinet 10 being provided in an open state, and the cover 20 being used to open or cover the opening of the cabinet 10. The two hinge mechanisms 30 are arranged at intervals, each hinge mechanism 30 is respectively connected with the cover plate 20 and the cabinet 10, each hinge mechanism 30 comprises a first connecting seat 31, a second connecting seat 32 and a connecting assembly, the first connecting seat 31 is arranged on the cover plate 20, the length direction of the first connecting seat 31 is parallel to the width direction of the cover plate 20, and a sliding block 33 capable of sliding along the length direction of the first connecting seat 31 is arranged on the first connecting seat 31. The second connecting seat 32 is arranged in the box body 10, the length of the second connecting seat 32 is smaller than that of the first connecting seat 31, and the connecting components are hinged with the first connecting seat 31, the sliding block 33 and the second connecting seat 32 respectively. When the cover 20 is at the maximum open/close position, a part of the body of the cover 20 moves to the rear side of the cabinet 10, and the centroid of the cover 20 is located above the top surface of the cabinet 10 and is close to the top surface of the cabinet 10. The embodiment also provides a generator set, which comprises the case.

According to the case and the generator set disclosed by the embodiment, when the cover plate 20 is positioned at the maximum opening and closing position, the mass center of the cover plate 20 is positioned above the top surface of the cabinet 10 and approaches the top surface of the cabinet 10, and as part of the plate body of the cover plate 20 moves to the rear side of the cabinet 10, the windward area of the inner side of the cover plate 20 becomes smaller, and wind is not easy to blow the cover plate 20 in the opening state, so that the cover plate 20 can still be kept in the opening state, the problem that the opened cover plate 20 is easily closed due to wind blowing is avoided, the integral windproof and wind-resistant effects of the cover plate 20 and the case are improved, the potential safety hazard is reduced, and the normal use of the case is ensured. Meanwhile, the hinge mechanism 30 is not exposed outside, so that the service life of the hinge mechanism 30 is prolonged, and the firmness of the connection of the cover plate 20 and the cabinet 10 is ensured. Meanwhile, the first connecting seat 31 with a long length is installed on the cover plate 20, and the second connecting seat 32 with a short length is installed in the cabinet 10, so that the second connecting seat 32 with a short length does not occupy the inner space of the cabinet 10 too much, thereby not affecting the installation of other parts.

In one embodiment, two reinforcing beams 21 are provided on the inner side of the cover 20, the reinforcing beams 21 extend along the width direction of the cover 20, and each reinforcing beam 21 corresponds to one first connecting seat 31, and the first connecting seat 31 is mounted on the reinforcing beam 21. The first reinforcement beam 21 is designed to not only play a role in connecting the first connection base 31, but also realize connection between the first connection base 31 and the cover plate 20. At the same time, the reinforcing beam 21 also improves the structural strength of the cover plate 20, and reduces the possibility of deformation of the cover plate 20.

Further, the reinforcement beam 21 is provided with a first mounting member 40, the first mounting member 40 includes a first plate 41 and a second plate 42 connected to each other, the first plate 41 is provided on the reinforcement beam 21, a yielding gap 50 is provided between the second plate 42 and the reinforcement beam 21, and the first connecting seat 31 is provided on one side of the second plate 42 facing away from the reinforcement beam 21. The first plate 41 is fastened to the reinforcement beam 21 by means of bolts, while the second plate 42 is fastened to the first connection socket 31 by means of bolts. In addition, the design of the yielding gap 50 facilitates yielding the position of the nut 43 when the second plate 42 is connected with the first connecting seat 31.

Further, the first connecting seat 31 is provided with a plurality of first through holes, and the second plate 42 is provided with a plurality of second through holes, and each second through hole corresponds to one first through hole. The second plate 42 is fixedly provided with a plurality of nuts 43, the nuts 43 are located in the yielding gaps 50, and each nut 43 corresponds to one second through hole. The nut 43 is fixed on the second plate 42 by welding, and the operator can conveniently and rapidly install the first connecting seat 31 on the second plate 42 by fixing the nut 43 on the second plate 42 in advance.

In one embodiment, the connection assembly includes a first connection arm 34, a second connection arm 35, and a third connection arm 36, two ends of the first connection arm 34 are hinged to the first connection seat 31 and the second connection seat 32, respectively, and a hinge position of the first connection arm 34 and the first connection seat 31 is close to the front side of the cover plate 20. Two ends of the second connecting arm 35 are respectively hinged with the sliding block 33 and the second connecting seat 32, and two ends of the third connecting arm 36 are respectively hinged with the first connecting arm 34 and the sliding block 33. The connecting assembly further comprises a fourth connecting arm 37, and two ends of the fourth connecting arm 37 are respectively connected with the third connecting arm 36 and the second connecting seat 32. The structural design of the connecting assembly makes the bearing capacity of the first connecting seat 31 stronger, the weight and wind resistance effect of the cover plate 20 can be adapted better, and the third connecting arm 36 and the fourth connecting arm 37 can also be used as auxiliary supporting arms, so that the bearing capacity of the hinge mechanism 30 is further improved.

In one embodiment, the second mounting member 60 and the third mounting member 70 are disposed in the cabinet 10, the two second connecting seats 32 are respectively disposed on the second mounting member 60 and the third mounting member 70, the third mounting member 70 is provided with a third through hole 71, and the side plate of the cabinet 10 adjacent to the third mounting member 70 is provided with a shutter 11. The third mount 70 divides the inner cavity of the cabinet 10 into a first chamber 12 and a second chamber 13, the first chamber 12 communicates with a third through hole 71 of the second chamber 13, and the second chamber 13 is located between the third through hole 71 and the louver 11. The high temperature air flow generated by the internal combustion engine of the generator set is discharged out of the cabinet 10 through the third through hole 71, the second chamber 13 and the louver 11, thereby avoiding the high temperature air flow from staying in the cabinet 10, so that the generator set can be operated in a normal temperature state.

In the description of the present application, numerous specific details are set forth. However, it is understood that embodiments of the present application may be practiced without these specific details. In some instances, well-known methods, structures and techniques have not been shown in detail in order not to obscure an understanding of this description.

It should be noted that the above embodiments are only used to illustrate the technical solution of the present application, but not to limit the technical solution of the present application, and although the detailed description of the present application is given with reference to the above embodiments, it should be understood by those skilled in the art that the technical solution described in the above embodiments may be modified or some or all technical features may be equivalently replaced, and these modifications or substitutions do not make the essence of the corresponding technical solution deviate from the scope of the technical solution of the embodiments of the present application, and all the modifications or substitutions are included in the scope of the claims and the specification of the present application.

1. A chassis comprising:
a cabinet with an opening at a top of the cabinet;
a cover plate for opening or covering the opening; and
a hinge mechanism arranged at intervals, the hinge mechanism respectively connected with the cover plate and the cabinet, the hinge mechanism including first connecting seats, second connecting seats and connecting components, wherein the first connecting seats are arranged on the cover plate, wherein length directions of the first connecting seats are parallel to a width direction of the cover plate;
sliding blocks capable of sliding along the length directions, wherein the second connecting seats are arranged in the cabinet, wherein the lengths of the second connecting seats are less than that of the first connecting seats, and the connecting components are respectively hinged with the first connecting seats, the sliding blocks, and the second connecting seats;
wherein a part of a plate body of the cover plate is configured to move to the rear side of the cabinet when the cover plate is positioned at a maximum opening or closing position, and a mass center of the cover plate is positioned above the top surface of the cabinet and is adjacent to a top surface of the cabinet.

2. The chassis according to claim 1, wherein two reinforcement beams are provided on an inner side of the cover plate, wherein the reinforcement beams extend along the width direction of the cover plate, each reinforcement beam corresponds to the first connection seats that are provided on the reinforcement beams.

3. The chassis according to claim 2, wherein each reinforcement beam is provided with a first mounting member that includes a first plate body and a second plate body that are connected to each other, wherein the first plate body is arranged on each reinforcement beam, wherein a yielding gap is formed between the second plate body and each reinforcement beam, and the first connecting seats are arranged on one side, away from each reinforcement beam, of the second plate body.

4. The chassis according to claim 3, wherein the first connection seats are provided with a plurality of first through holes, wherein the second plate body is provided with a plurality of second through holes, and each second through hole corresponds to one first through hole; and a plurality of nuts fixedly arranged on the second plate body, wherein the nuts are located in the yielding gap, and each nut corresponds to one second through hole.

5. The chassis according to claim 1, wherein connection assemblies comprise first connection arms, second connection arms, and third connection arms, wherein two ends of each first connection arm are hinged to a respective first connection seat and a respective second connection seat, wherein two ends of each second connection arm are hinged to a respective sliding block and the respective second connection seat, and wherein two ends of each third connection arm are hinged to the respective first connection arm and the respective sliding block.

6. The chassis according to claim 5, wherein each connection assembly further comprises a fourth connection arm, wherein both ends of the fourth connection arm are respectively connected to the third connection arm and the second connection base.

7. The chassis according to claim 1, wherein a second mounting member and a third mounting member are disposed in the cabinet, wherein the two second connecting seats are respectively disposed on the second mounting member and the third mounting member, wherein a third through hole is disposed on the third mounting member, and wherein a louver is disposed on a side plate of the cabinet adjacent to the third mounting member.

8. The cabinet according to claim 7, wherein the third mounting member divides an inner cavity of the cabinet into a first chamber and a second chamber, wherein the first chamber communicates with the second chamber through-hole and the third through-hole, and the wherein the second chamber is located between the third through-hole and the louver.

9. A generator set comprising the chassis as claimed in any one of claims 1 to 8.
